(19) United States
(12) Patent Application Publication
(10) Pub. No.: US 2011/0031001 A1
(43) Pub. Date: Feb. 10, 2011

(54) COMPOSITE METAL FINE PARTICLE MATERIAL, METAL FILM AND MANUFACTURING METHOD OF THE METAL FILM, AND PRINTED WIRING BOARD AND CABLE

(75) Inventors: Dai ISHIKAWA, Hitachi-shi (JP); Tomiya ABE, Hitachi-shi (JP); Masanobu ITO, Hitachi-shi (JP)

Correspondence Address: Fleit Gibbons Gutman Bongini & Bianco PL, 21355 EAST DIXIE HIGHWAY, SUITE 115, MIAMI, FL, 33180, US

(73) Assignee: HITACHI CABLE LTD., Tokyo (JP)

(21) Appl. No.: 12/701,676

(22) Filed: Feb. 8, 2010

(30) Foreign Application Priority Data
Aug. 10, 2009 (JP) 2009-185467

(51) Int. Cl. H05K 1/09; B32B 15/04; B22F 7/04; B22F 1/02; H01B 9/02

(52) U.S. Cl. 174/257; 428/548; 419/9; 75/255; 428/570; 174/102 R

(57) ABSTRACT

A composite metal fine particle material is provided, in which spherical silver nanoparticles synthesized from a silver compound, a solvent, a reducing agent, and a dispersant, and conductive fillers compose of non-spherical metal fine particles, are mixed. For example, the conductive fillers composed of the non-spherical metal fine particles are formed into slender columnar shapes, plate shapes, or ellipsoidal shapes.

### BACKGROUND

1. Technical Field

The present invention relates to a composite metal fine particle material in which silver nanoparticles and conductive fillers are mixed, a metal film formed by using this composite metal fine particle material, a manufacturing method of the metal film, and a printed wiring board and a cable.

2. Description of Related Art

A metal fine particle generally means the metal fine particle having a particle size of 100 nm or less. The metal fine particle having such a size has a considerably large surface area relative to a volume, and therefore is likely to have a remarkably low melting point, compared with a particle having a size of mm unit or several 100 μm unit. Therefore, diffusion of metal fine particles occurs in a particle interface, at a temperature lower than the melting point of a bulk metal, thus allowing fusion to be accelerated, resulting in forming metal binding.

By utilizing such a feature, the metal fine particle is used in conductive materials such as a conductive ink and a conductive paste, as a so-called metal nanoparticle.

However, in the conventional conductive ink and the conductive paste using a conventional metal fine particle, the conductivity of the same level as that of the bulk metal is hardly exhibited, under sintering conditions of a low temperature of 300° C. or less and a short time of 10 minutes or less. Mainly the following two causes can be given as causes for the difficulty of obtaining an excellent conductivity by sintering under conditions of the low temperature and short time.

As a first cause, residues of a solvent and a protective agent can be given. Under the sintering conditions of low temperature and short time, the solvent contained in the conductive materials and the protective agent on the surface of the metal fine particle are remained without being sufficiently vaporized or decomposed, thus inhibiting conductivity by the residual solvent and protective agent. However, regarding the residues of the solvent and the protective agent, a certain degree of improvement is expected, by selecting the solvent and the protective agent that can be vaporized or decomposed at a low temperature, or reducing a use amount of the solvent and the protective agent.

As a second cause, volume shrinkage of the metal film during sintering that occurs in fusion of metal nanoparticles and volatilization of the solvent, can be given. This volume shrinkage causes lots of cracks and grain boundaries to be generated in the metal film, thereby causing deterioration of the conductivity. As a method of solving this problem, it can be considered that components of the solvent in the conductive materials and a dispersant are reduced and also metal components are increased to obtain high concentration of the metal components, thus making it difficult to cause the volume shrinkage of the metal film to occur. However, in a case of not using an adequate amount of solvent and dispersant, metal fine particles are flocculated with high concentration of the metal, resulting in forming a great secondary particle. Also, since viscosity of the conductive material is tremendously increased with high concentration of the metal, further inconvenience is generated, such that a proper viscosity required in practical use as the conductive ink and the conductive paste can not be obtained. Thus, there is a problem that another inconvenient situation is invited by a method of simply making the metal components highly concentrated.

Further, when a sufficiently great metal particle having a particle size of, for example, a micro meter size is used for the volume shrinkage of the metal film, a volume ratio of the metal particle that occupies in the metal film becomes larger than the volume ratio of the metal nanoparticle. Accordingly, it can be considered that there is a high physical contact probability of the metal particles, thereby easily forming a conducting path of a current. However, such a metal particle having the size of micro meter has the same degree of melting point as that of the bulk metal, and therefore sintering under process conditions of low temperature and short time is difficult or impossible principally.

As a specific example of the conductive material according to the conventional art, as schematically shown in FIG. 5, patent document 1 discloses a conductive metal paste with metal fine particles 101 having an average particle size of 1 nm to 100 nm composed of silver (Ag), gold (Au), copper (Cu), etc, and metal fillers 102 having an average particle size of 0.5 μm to 20 μm, dispersed in a resin composition in the form of varnish (not shown).

Also, as schematically shown in FIG. 6, patent document 2 discloses a conductive composition containing silver nanoparticles 111 having an average particle size of less than 10 nm, powdery metal fillers 112 having an average particle size of 0.01 μm to 10 μm composed of Au, Ag, and Cu, etc, and silver oxide particles 113 having an average particle size of 0.01 μm to 10 μm.

### RELATED ART DOCUMENTS

(Patent document 1) WO2002/035554
(Patent document 2) Japanese Patent Laid Open Publication No. 2007-42301

However, in the conductive materials disclosed in the aforementioned patent documents 1 and 2, a sintering temperature can be lowered to be 200° C. or less. However, its sintering time is prolonged to be 60 minutes or more, and a long time is required compared with the sintering time of a targeted short time such as about 10 minutes. When a long time sintering process is required, production efficiency in an actual production line is lowered accordingly.

Further, in the conductive material disclosed in the patent document 2, silver oxide particles composed of silver oxide (Ag₂O) is indispensable. However, if we try to complete sintering in an extremely short time such as about 10 minutes, being a target time, gaseous oxygen (O₂) is generated from the silver oxide during sintering process, and when this gaseous oxygen gets out of the conductive paste in the form of bubbles, there is a high possibility that a void part as a trace of the bubbles is hardened, resulting in porous defects.

### SUMMARY OF THE INVENTION

An object of the present invention is to provide a composite metal fine particle material capable of exhibiting sufficient conductivity by sintering at a low temperature in a short time, a metal film formed by sintering this composite metal fine particle material, and a manufacturing method of the metal film.

An aspect of the present invention is a composite metal fine particle material in which spherical silver nanoparticles synthesized from a silver compound, a solvent, a reducing agent, and a dispersant, and conductive fillers composed of non-spherical metal fine particles, are mixed.

An aspect of the present invention is a metal film formed by coating a surface of a base material with the composite metal fine particles material, and sintering the coated composite metal fine particle material.

An aspect of the present invention is a manufacturing method of the metal film including the steps of:

coating a surface of a base material with a composite metal fine particle material, in which spherical silver nanoparticles are synthesized by using a silver compound, a solvent, a reducing agent, a dispersant, and conductive fillers composed of non-spherical metal fine particles, being dispersed in a solvent;

setting in a sintering furnace, the base material the surface of which is coated with the composite metal fine particle material; and

forming a metal film by sintering the composite metal fine particle material on the surface of the base material, with temperature/time conditions in the sintering furnace set to be 300° C. or less and 10 minutes or less.

### BRIEF DESCRIPTION OF THE DRAWINGS

FIG. 1 is a view schematically showing a main essential structure of a composite metal fine particle material according to an embodiment of the present invention.

FIG. 2 is a view schematically showing the structure of a metal film formed by sintering the composite metal fine particle material according to an embodiment of the present invention.

FIG. 3 is a plan view of a printed wiring board according to an embodiment of the present invention.

FIG. 4 is a sectional view of a cable according to an embodiment of the present invention.

FIG. 5 is a view schematically showing a main essential structure of a conventional conductive material.

FIG. 6 is a view schematically showing the main essential structure of a conventional conductive material.

### DESCRIPTION OF PREFERRED EMBODIMENTS OF THE INVENTION

A composite metal fine particle material and a metal film and a manufacturing method of the metal film according to preferred embodiments of the present invention will be described hereinafter, with reference to the drawings.

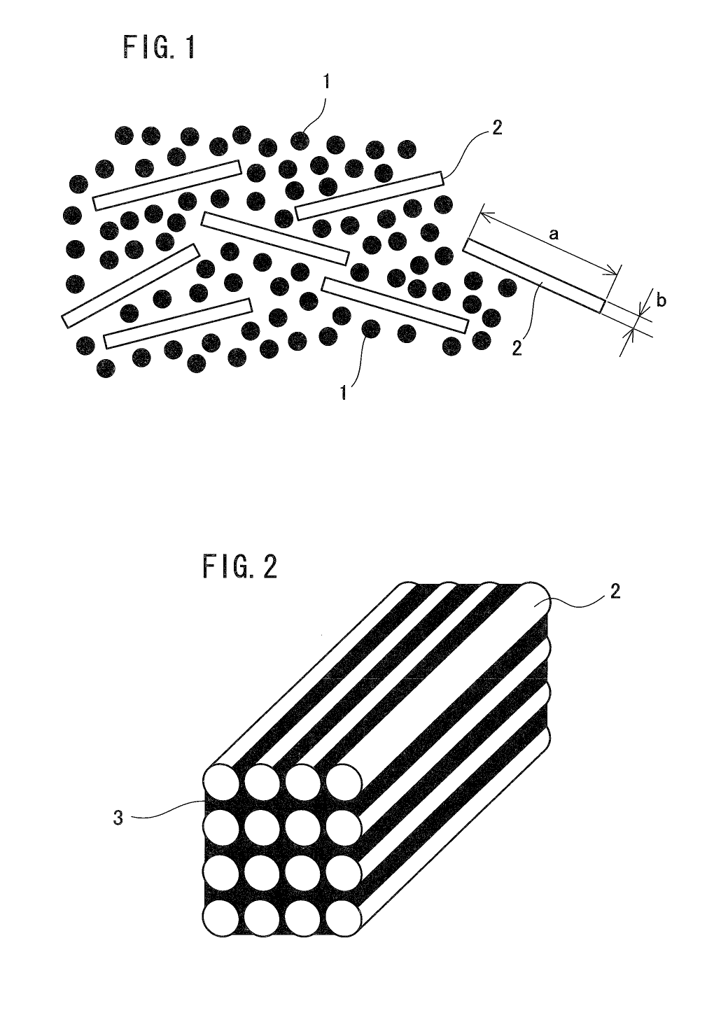

As schematically shown in FIG. 1, the composite metal fine particle material according to an embodiment of the present invention is a powdery composite metal fine particle material in which spherical silver nanoparticles 1 synthesized by using a silver compound, a solvent, a reducing agent, and a dispersant, and conductive fillers 2 composed of non-spherical metal fine particles are mixed. Alternately, it is the composite metal fine particle material in the form of a paste, with a powdery composite metal fine particle material in which the aforementioned nanoparticles land conductive fillers 2 are mixed, dispersed in a solvent (not shown) such as a toluene solvent.

The silver nanoparticles 1 is sintered by a sintering process at a low temperature of 300° C. or less and in a short time of 10 minutes or less, to thereby form a metal film.

As the silver compound used in synthesizing the silver nanoparticles 1, silver carbonate, silver nitrate, silver chloride, silver acetate, silver formate, silver citrate, silver oxalate, or fatty acid silver salt having 4 or less carbon atoms can be given as salts of silver (Ag), and other than these silver salts, a silver complex can be given. At least any one of these silver compounds is used in synthesis. These silver compounds are reduced by being heated in the solvent added with the reducing agent, to thereby generate nuclei, becoming the silver nanoparticles 1, which is then grown and is stopped to grow with a prescribed size of a nano size, to thereby obtain spherical silver nanoparticles 1. It is desirable to set an average particle size of the silver nanoparticles 1 to be 20 nm or less, as a specific numerical aspect. This is because when the average particle size of the silver nanoparticles 1 exceeds 20 nm, this particle size less contributes to lowering a melting point in the silver nanoparticles 1 themselves, and it becomes difficult to perform sintering at a low temperature in a short time.

As the solvent that can be used in synthesizing the silver nanoparticles 1, alcohols, aldehydes, amines, monosaccharide, polysaccharide, straight-chain hydrocarbons, fatty acids, and aromatic compounds can be given. The solvent showing compatibility to the dispersant used for synthesis is particularly desirable. Further, the solvent having a boiling point of 200° C. or less is desirable to satisfy the purpose of performing sintering under conditions of low temperature/short time.

As the reducing agent that can be used for the synthesis of the silver nanoparticles 1, alcohols, aldehydes, amines, lithium aluminium hydroxide, sodium thiosulfate, hydrogen peroxide, hydrogen sulfide, borane, diborane, hydrazine, potassium iodide, citric acid, oxalic acid, and ascorbic acid, can be given. In order to stop the growth of the particles when a desired fine particle size is obtained by successfully controlling the reduction of the silver salt (metal salt), it is desirable to set an addition amount of the reducing agent contained in a reducing solvent, so that a concentration ratio of the reducing agent to the silver salt (concentration ratio of the reducing agent/silver salt) is 0.1 or more and 3.0 or less. This is because when the concentration ratio of the reducing agent is set to be less than 0.1, a reduction rate of the silver compound is remarkably decreased, thus making it difficult to obtain desired spherical silver nanoparticles 1 within a practical time, and when the concentration ratio of the reducing agent exceeds 3.0, the reduction of the silver compound is remarkably accelerated, thus unpreferably making the particle size of the silver nanoparticles excessively large and increasing variations in the particle size.

As the dispersant that can be used in the synthesis of the silver nanoparticles 1, molecule species having a chemical affinity for the silver nanoparticles 1 and the solvent is desirable. Further, in order to perform sintering at a low temperature, a compound having further low boiling point is desirable. Specifically, a compound having a thiol group (—SH) and an amine group (—NH₂) or each kind of surfactant agent can be used. A thiol compound and an amine compound are coordinatively bonded to the surface of a metal fine particle by utilizing an unshared electron pair on a sulfur element and a nitrogen element. Therefore, cohesion of silver particles (metal fine particles) can be suppressed. Further, the thiol compound and the amine compound showing affinity for the solvent have a function of uniformly dispersing the silver particles into the solvent, and therefore in this point also the thiol compound and the amine compound are preferable.

An addition amount of the dispersant is preferably set to be in a range of not excessive amounts to silver (metal), and is specifically set to be in a range not exceeding 3 mol at maximum, or is more preferably set to be 0.5 mol or more and 2.0 mol or less. This is because when it is set to be less than 0.5 mol, the silver particle is not sufficiently coated, thus easily causing cohesion to occur and an apparent particle size to be enlarged. Reversely, when it is set to be an amount exceeding 3 mol, an excess dispersant exists on the surface of the silver particle, which is hardly removed, resulting in a state that the dispersant easily remains on the surface of the silver particle without departing therefrom when the silver nanoparticles are sintered.

Non-spherical metal fine particles of the conductive fillers 2 are formed into a slender columnar shape, a strip shape (long rectangular shape), and a slender ellipsoidal shape, with long axis direction (including a direction that can be regarded as the long axis) set to be length “a” and a short axis direction (including a direction that can be regarded as the short axis) which is different from the aforementioned direction set to be length “b” (Therefore, the shape of the conductive fillers 2 is called “non-spherical”). The length “a” in the long axis direction of the non-spherical metal fine particles is preferably set to be 10 nm or more and 1000 nm or less, and is further preferably set to be 30 nm or more and 1000 nm or less. Further, the aspect ratio (a/b), being the ratio of the length “a” in the long axis direction to the length “b” in the short axis direction in the non-spherical metal fine particles, is preferably set to be 4 or more and 50 or less.

The conductive fillers 2 are made of metal selected from any one of palladium (Pd), platinum (Pt), gold (Au), silver (Ag), copper (Cu), and nickel (Ni). The conductive fillers 2 composed of non-spherical metal fine particles are synthesized by using a metal compound containing metal selected from any one of the aforementioned elements, ethylene glycol, and polyvinylpyrrolidone.

If the length “a” in the long axis direction of the conductive fillers 2 becomes greater than 1000 nm, a volume ratio of the conductive fillers 2 occupying in the composite metal fine particle material becomes excessively large. Therefore, sintering is not sufficiently accelerated under process conditions of low temperature and short time, resulting in a decrease of the conductivity of the metal film obtained by sintering. Further, a coating property and a film-forming property are deteriorated, thus making it difficult to form a thin film with high quality. Meanwhile, if the length “a” of the conductive fillers 2 in the long axis direction becomes less than 10 nm, the aspect ratio is decreased relatively, and therefore its outer shape becomes close to a spherical shape. As a result, a contact area of the conductive fillers 2, and a contact area of conductive fillers 2 and silver nanoparticles 1 becomes small to the same degree as the case of the conductive fillers composed of conventional spherical metal fine particles, thus making it difficult or impossible to obtain a sufficient conductivity. Accordingly, the length “a” of the conductive fillers 2 in the long axis direction is preferably set to be 10 nm or more and 1000 nm or less, or more preferably set to be 30 nm or more and 1000 nm or less.

Further, by setting the length “a” of the conductive fillers 2 in the long axis direction to 10 nm or more and 1000 nm or less, and setting the aspect ratio (a/b) to be within a range of 4 or more and 50 or less, a melting point lowering phenomenon specific to the metal fine particles is slightly observed in the conductive fillers 2 themselves. Therefore, not only a simple physical contact with the silver particles 1, but also metal binding with the silver nanoparticles 1 that accompanies diffusion of metal atoms is easily formed, and as a result, further higher conductivity can be developed. For this reason, the aspect ratio (a/b), being the ratio of the length “a” in the long axis direction to the length “b” in the short axis direction, is preferably set to be within a range of 4 or more and 50 or less.

Further, mass % of the conductive fillers 2 in total mass of the composite metal fine particle material, in which the silver nanoparticles 1 and the conductive fillers 2 are mixed, is preferably set to be 1 mass % or more and 20 mass % or less. In other words, the ratio of the silver nanopartciles 1 to the conductive fillers 2 by mass % (mass % of the silver nanoparticles 1:mass % of the conductive fillers 2) is preferably set to be a value within 99:1 to 80:20.

This is because when the mass ratio of the conductive fillers 2 is less than 1 mass %, it is difficult to secure a sufficient contact between the conductive fillers 2, and crack and a grain boundary cracking are easily generated after sintering, thus making it impossible to obtain a sufficient conductivity. Further, when the mass ratio of the conductive fillers 2 exceeds 20 mass %, the volume ratio of the conductive fillers 2 occupying in the composite metal fine particle material becomes excessively large, thus making it difficult to perform sintering at a low temperature.

In the composite metal fine particle material according to the embodiment of the present invention, the conductive fillers 2 composed of the metal fine particles having a columnar shape such as a circular columnar shape and a polygonal shape, the non-spherical shape such as a plate shape (rectangular shape) or an ellipsoidal shape, or a spindle shape, and a so-called slender shape, are mixed with the silver nanoparticles 1. Therefore, in a case of the conductive fillers 2 composed of slender-shaped non-spherical metal fine particles, the physical contact between the metal fine particles is likely to occur not as a point contact but as a face-to-face contact and a line contact at the time of sintering, and therefore a contact area can be taken large. Thus, in the metal film obtained by sintering, there is a high probability that a series of conducting path for electrical conduction can be formed. Further, since the contact area of the surface of the conductive fillers 2 is large, fusion between the conductive fillers 2 and the silver nanoparticles 1 occurs easily. Under combination of these actions, if the composite metal fine particle material according to the embodiment of the present invention is used, the metal film having excellent conductive property can be obtained, by a sintering process under processing conditions of low temperature and short time, namely by sintering process with high production efficiency.

When the metal film is formed by using the composite metal fine particles according to the aforementioned embodiment, the surface of a base material is coated with the composite metal fine particle material, then the base material coated with the composite metal fine particle material is set in a sintering furnace, which is then sintered under processing conditions of 300° C. or less and 10 minutes or less, thereby making it possible to form the metal film having sufficient conductivity on the surface of the base material.

At the time of sintering, although a slight volume shrinkage occurs in the metal film, the contact area of the slender conductive fillers 2 is large as already described and the conducting path can be secured. Therefore, complete disconnection of the finished metal film can be suppressed or avoided. As a result, the metal film having sufficiently excellent conductivity can be obtained even in a sintering process at a low temperature of about, for example, 200° C. to 300° C. and in a short time of 10 minutes or less.

As schematically shown in FIG. 2, the structure of the metal film is that, for example, a plurality of slender columnar conductive fillers 2 are arranged in approximately the same direction, and a remolten solid 3 after melting the silver nanoparticles 1 is filled in the gap between the conductive fillers 2. Here, FIG. 2 shows a condition in which tip ends and rear ends of all conductive fillers 2 are regularly arranged, for convenience of simplifying the figure. However, actually, in most of the cases, the end portion of each of the plurality of conductive fillers 2 is arranged so as to be deviated mutually in front and rear positions in the longitudinal direction, and in many cases, the adjacent conductive fillers 2 are varied without being arranged in the same direction, and also the adjacent conductive fillers 2 are directly brought into contact with each other not through the remolten solid 3 after melting the silver nanoparticles 1. In this case also, there is a high probability that a series of the electric conductive path can be secured owing to an existence of the slender conductive fillers 2.

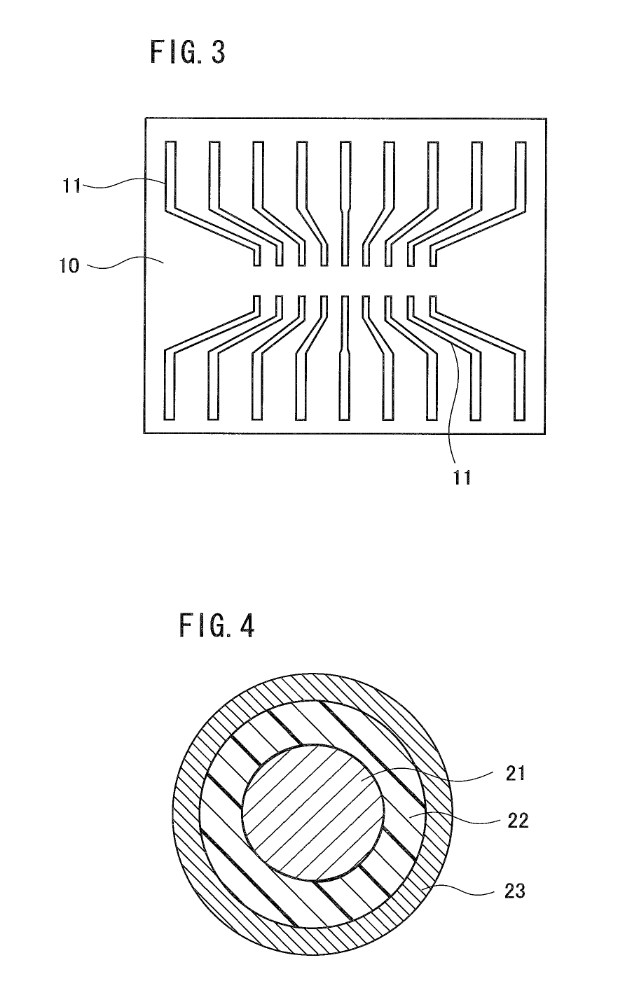

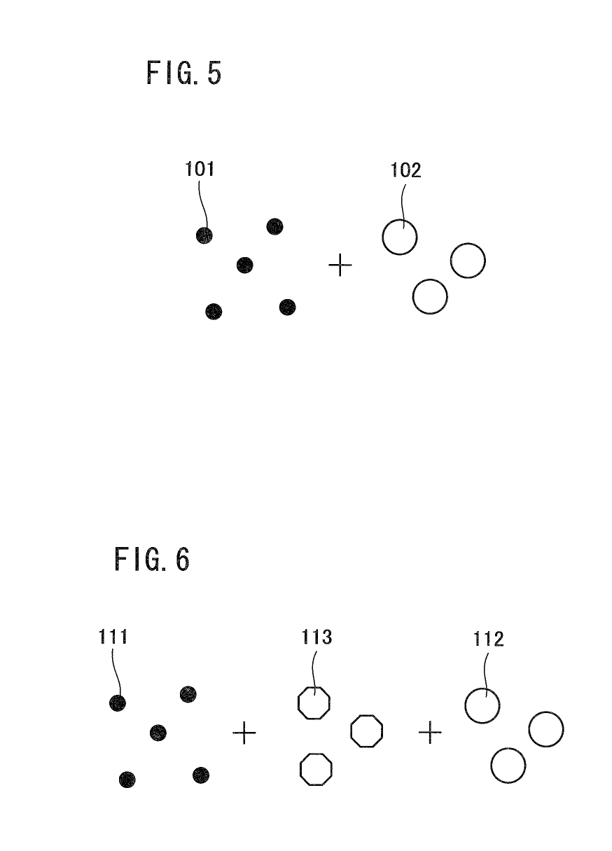

Further as shown in FIG. 3, when linear wiring patterns 11 are formed on the surface of an insulating substrate 10 to fabricate a printed wiring board, a paste-like composite metal fine particle material is applied to surface of the insulating substrate as desired wiring patterns, for example, by a print method, or desired wiring patterns are drawn, while discharging the paste-like composite metal fine particle material from a nozzle to the surface of the insulating substrate at a prescribed discharging speed. At this time, by a hydrodynamic force and a surface tension that works in coating and injecting the paste-like composite metal particle material, there is a high probability that the long axis direction of the non-spherical conductive fillers 2 dispersed in the paste-like composite metal fine particle material is likely to be arranged in a longitudinal direction of the wiring patterns 11 or in a direction parallel to the surface of the insulating substrate 10. Accordingly, there is a further probability that the conductive fillers 2 form a series of the electric conductive path along the longitudinal direction of the wiring patterns, and therefore we consider it possible to surely secure the sufficient conductivity.

Further, the metal film according to this embodiment can be applied not only to the printed wiring board having the aforementioned wiring patterns but also to a cable. Namely, as shown in FIG. 4, the metal film of this embodiment is also applied to a coaxial cable, with an insulating layer 22 being formed on a periphery of an electric conductive wire 21, and an electric conductive layer 23 made of a metal film of this embodiment being further formed on the periphery of the insulating layer 22. Further, according to the present invention, the metal film can also be applied to an electric line having a linear electric conductive wire formed by using the composite metal fine particle material according to this embodiment.

Further, it is also possible that the composite metal fine particle material of the present invention is traded as a product in a state of dispersing the silver nanoparticles land the conductive fillers 2 in a solvent and in addition as a product in a powder state formed by, for example, mixing the silver nanoparticles 1 and the conductive fillers 2, and when this product is actually used by a user, the solvent most suitable for the purpose of use at this time is selected, and by dispersing a powder-like composite metal fine particle material into this solvent, a paste material is fabricated and used.

### Examples

### <Manufacture of Spherical Silver Nanoparticles>

The spherical silver nanoparticles 1 as described in the aforementioned embodiment are manufactured (synthesized) by specifications of two kinds.

### (1) First Specification

First, a solution was prepared, which was obtained by adding silver nitrate 1.7 g as a silver compound, toluene 45 mL as a solvent, triethylamine 1.0 g as a dispersant, and ascorbic acid 1.76 g as a reducing agent to an eggplant-shaped flask of 100 mL. Then, the solution was refluxed for 1 hour at 110° C. while being stirred. Thereafter, the solution was cleaned by methanol and powders were recovered.

When an X-ray diffraction measurement was performed to the obtained powders, the powders were confirmed to be silver metal having face-centered cubic (fcc) structure. Further, silver content percentage in the powders was calculated to be about 80 mass %.

A dispersion solution was prepared, with the powders re-dispersed in a toluene. When plasmon absorption of this dispersion solution was measured, it was confirmed that the plasmon absorption specific to the silver nanoparticles 1 was exhibited near wavelength 420 nm.

Then, when the particle size distribution of the powders was measured, an average particle size was about 8 nm. Further, the silver nanoparticles with particle size of about 8 nm were also observed by Field Emission-Scanning Electron Microscope (FE-SEM).

Here, a powder X-ray diffactometer; RINT2000 (by Rigaku Corporation) was used in the X-ray diffraction measurement. This powder X-ray diffractometer was also used in a case that a metal component needs to be identified at the time of the manufacture of the conductive fillers as will be described later.

Further, a thermo gravimetry differential thermal analyzer (TG/DTA); TG8120 (by Rigaku Corporation) was used in measuring a content of the metal components. This TG/DTA was also used in a case of measuring the content of the metal components in manufacturing the conductive fillers as will be described later.

Further, in the measurement of plasmon absorption, a ultraviolet-visible absorption spectrophotometer; V-550 (by JASCO Corporation) was used. Note that the silver nanoparticles with a size of about several nm to 100 nm have generally absorption near the wavelength 420 nm, by surface plasmon resonance.

Further, a laser Doppler dynamic light scattering device; UPA-EX150 type (by NIKKISO Corporation) and FE-SEM; S-5000 (by HITACHI Ltd.) were used in the measurement of the average particle size. Here, the average particle size means the average size obtained from the particle size distribution of the measured particle size, and the average size means the particle size of 50% of integrated values obtained by integrating the particle size distribution from the side of a small particle size. Then, FE-SEM; S-5000 (by HITACHI Ltd.) was used in observing an outer shape of a particle and an outline of the particle size. The laser Doppler dynamic light scattering device and FE-SEM were also used in manufacturing the conductive fillers as will be described thereafter.

### (2) Second Specification

First, a solution was prepared, which was obtained by adding silver acetate 1.65 g as a silver compound, hexane 45 mL as a solvent, triethylamine 1.0 g as a dispersant, and ascorbic acid 1.76 g as a reducing agent to the eggplant-shaped flask of 100 mL. Then, the solution was refluxed for 1 hour at 70° C. while being stirred. Thereafter, the solution was cleaned by methanol and powders were recovered.

When the X-ray diffraction measurement was performed to the obtained powders, it was confirmed to be silver metal (Ag) having fcc structure. The content percentage of silver in the powders was calculated to be about 85 mass %.

The dispersion solution was prepared, with the powders re-dispersed in a toluene. When plasmon absorption of this dispersion solution was measured, it was confirmed that the plasmon absorption specific to the silver nanoparticles 1 was exhibited near wavelength 420 nm.

Then, when the particle size distribution of the powders was measured, an average particle size was about 15 nm. Further, the silver nanoparticles having particle size of about 15 nm were also observed by FE-SEM.

### <Manufacture of the Non-Spherical Conductive Fillers>

The non-spherical conductive fillers 2 as described in the aforementioned embodiment were manufactured by specifications of two kinds.

### (1) First Specification

First, a solution was prepared, which was obtained by adding silver nitrate 0.081 g, ethylene glycol 22.5 mL, polyvinylpyrrolidone (molecular weight was about 10000 g/mol) 0.295 g, hydrogen hexachloroplatinate (IV) hexahydrate 0.60 mg as a nucleation agent, to the eggplant-shaped flask of 100 mL. Then, the solution was refluxed for about 3 minutes at 198° C. while being stirred. Thereafter, the solution was filtered by a filter having a pore size of 2 μm, and was further cleaned by methanol, and the powders were recovered.

From the observation of the obtained powders by FE-SEM, it was confirmed that the powders were conductive fillers composed of columnar and plate-shaped silver particles, with the length “a” in the long axis direction set to be 50 nm to 200 nm.

### (2) Second Specification

First, a solution was prepared, which was obtained by adding hydrogen tetrachloroaurate (III) tetrahydrate 0.020 g, ethylene glycol 20.0 mL, polyvinylpyrrolidone (molecular weight was about 40000 g/mol) 0.577 g, to the eggplant-shaped flask of 100 mL. Then, the solution was refluxed for about 5 minutes at 198° C. while being stirred. Thereafter, the solution was filtered by a filter having a pore size of 2 μm, and was further cleaned by methanol, and powders were recovered.

From the observation of the obtained powders by FE-SEM, it was confirmed that the powders were conductive fillers composed of plate-shaped (strip-shaped) metal fine particles, with the length “a” in the long axis direction set to be 50 nm to 100 nm.

### <Manufacture of the Metal Film>

The metal film was manufactured by sintering, by using the composite metal fine particle material formed by mixing the silver nanoparticles 1 and the conductive fillers 2 as described in the aforementioned embodiment.

### Metal Film According to Example 1

By mixing the silver nanoparticles based on the first specification and the conductive fillers base on the first specification, and the composite metal fine particle material was prepared based on the first specification, which were then dispersed in the toluene solvent to obtain a conductive paste according to example 1.

The surface of a glass board (not shown) was coated with this conductive paste by spin coating, and the conductive paste was sintered under sintering conditions of 200° C. and 10 minutes in the atmosphere. As a result, it was confirmed that the obtained metal film according to the example 1 showed a satisfactory specific resistnace value of 3 times that of a bulk silver metal.

### The Metal Film According to Example 2

The silver nanoparticles based on the first specification and the conductive fillers based on the second specification were mixed, to thereby prepare the composite metal fine particle material based on the second specification, which was then dispersed in the toluene solvent, to obtain a conductive paste according to example 2.

The surface of the glass board (not shown) is coated with this conductive paste by spin coating. Then, the conductive paste was sintered under sintering conditions 300° C. and 10 minutes in the atmosphere. As a result, it was confirmed that the obtained metal film according to the example 2 showed an excellent specific resistance value of 5 times that of a bulk silver metal.

### The Metal Film According to Comparative Example 1

For comparison with metal films according to the examples 1 and 2, only silver nanoparticles based on the first specification were dispersed in the toluene solvent, to prepare the conductive paste according to comparative example 1, and in the same way as the example 1, the surface of the glass board was coated with this conductive paste and sintered under the conditions of 200° C. and 10 minutes, to obtain the metal film according to the comparative example 1. As a result, a plurality of cracks and grain boundaries were observed on the surface of the obtained metal film according to the comparative example 1, and an extremely high specific resistance value of 20 times that of the bulk silver metal (about 7 times that of the metal film according to the example 1). From this result, it was confirmed that the satisfactory conductivity could not be obtained when only the silver particles 1 were used without being mixed with the conductive fillers 2 of the present invention, used in the examples 1 and 2 of the present invention.

### The Metal Film According to Comparative Example 2

For comparison with the examples 1 and 2, only the conductive fillers based on the first specification were dispersed in the toluene solvent, to prepare the conductive paste according to comparative example 2, and the surface of the glass board was coated with this conductive paste in the same way as the example 1 and sintered under the conditions of 200° C. and 10 minutes, to obtain the metal film according to the comparative example 2. As a result, it was confirmed that in the obtained metal film according to the comparative example 2, a sufficient fusion was not accelerated and an extremely high specific resistance value of 40 times that of the bulk silver metal (13 times that of the metal film according to the example 1) was shown. From this result, it was confirmed that the satisfactory conductivity could not be obtained when only the non-spherical conductive fillers were used without being mixed with the spherical silver nanoparticles of the present invention, used in the examples 1 and 2 of the present invention.

### The Metal Film According to Comparative Example 3

For comparison with the examples 1 and 2, only the conductive fillers based on the second specification were dispersed in the toluene solvent, to prepare the conductive paste according to comparative example 3, and the surface of the glass board was coated with this conductive paste in the same way as the example 2 and sintered under the conditions of 300° C. and 10 minutes, to obtain the metal film according to the comparative example 3. As a result, it was confirmed that in the obtained metal film according to the comparative example 3, a sufficient fusion was not accelerated and an extremely high specific resistance value of 30 times that of the bulk silver metal (10 times that of the metal film according to the example 1) was shown. From this result, it was confirmed that the satisfactory conductivity could not be obtained when only the non-spherical conductive fillers made of gold were used without being mixed with spherical the silver nanoparticles of the present invention, used in the examples 1 and 2 of the present invention.

### The Metal Film According to Comparative Example 4

For comparison with the examples 1 and 2, the silver nanopartices based on the first specification and commercially available conventional spherical conductive fillers (spherical silver fine particles having average particle size of 3 to 4 μm) were mixed and dispersed in the toluene solvent, to prepare the conductive paste according to comparative example 4. Then, the surface of the glass board was coated with this conductive paste in the same way as the example 1 and sintered under the conditions of 200° C. and 10 minutes, to obtain the metal film according to the comparative example 4. As a result, it was confirmed that the obtained metal film according to the comparative example 4 showed an extremely high specific resistance value of 15 times that of the bulk silver metal (about 5 times that of the metal film according to the example 1), although slightly more satisfactory than the metal film according to the comparative examples 1, 2, 3.

For comparison with the metal film of the examples and the metal film of the comparative example, it was confirmed that according to the present invention, the metal film having sufficient conductivity could be sintered, with extremely high production efficiency, by a sintering process, for example, at a lower temperature of about 200° C. to 300° C. and in a short time of 10 minutes or less, which has been impossible by a conventional art.

What is claimed is:

1. A composite metal fine particle material, wherein spherical silver nanoparticles synthesized from a silver compound, a solvent, a reducing agent, and a dispersant, and conductive fillers composed of non-spherical metal fine particles, are mixed.

2. The composite metal fine particle material according to claim 1, wherein the conductive fillers composed of the non-spherical metal fine particles are formed into slender columnar shapes, plate shapes, or ellipsoidal shapes.

3. A composite metal fine particle material, wherein spherical silver nanoparticles coated with a dispersant, and conductive fillers composed of metal fine particles having columnar shapes, plate shapes, or slender shapes of ellipsoidal shapes, are mixed.

4. The composite metal fine particle material according to claim 1, wherein the conductive fillers composed of the non-spherical metal fine particles have a length in a long axis direction and a length in a short axis direction different from the length in the long axis direction in the metal fine particles, with an aspect ratio of the long axis/short axis set to be 4 or more and 50 or less.

5. The composite metal fine particle material according to claim 4, wherein the length of the long axis direction of the conductive fillers is set to be 10 nm or more and 1000 nm or less.

6. The composite metal fine particle material according to claim 1, wherein the conductive fillers composed of the metal fine particles include one kind metal of at least any one of Pd, Pt, Au, Ag, Cu, and Ni.

7. The composite metal fine particle material according to claim 1, wherein mass % of the conductive fillers in total mass of the composite metal fine particle material formed by mixing the silver nanoparticles and the conductive fillers, is 1 mass % or more and 20 mass % or less.

8. The composite metal fine particle material according to claim 1, wherein an average particle size of the spherical silver nanoparticles is 20 nm or less.

9. The composite metal fine particle material according to claim 1, wherein the composite metal fine particle material, in which the silver nanoparticles and the conductive fillers are mixed, is dispersed in a solvent.

10. The composite metal fine particle material according to claim 1, wherein the silver compound is one kind of at least any one of silver carbonate, silver nitrate, silver chloride, silver acetate, silver formate, silver citrate, silver oxalate, fatty acid silver salt having 4 or less carbon atoms, or a silver complex.

11. The composite metal fine particle material according to claim 1, wherein the solvent is one kind of at least any one of alcohols, aldehydes, amines, monosaccharide, polysaccharide, straight-chain hydrocarbons, fatty acids, and aromatic compounds.

12. The composite metal fine particle material according to claim 1, wherein the reducing agent is one kind of at least any one of alcohols, aldehydes, amines, lithium aluminium hydroxide, sodium thiosulfate, hydrogen peroxide, hydrogen sulfide, borane, diborane, hydrazine, potassium iodide, citric acid, oxalic acid, and ascorbic acid.

13. The composite metal fine particle material according to claim 1, wherein the dispersant is a compound having one group of at least any one of thiol group and amine group.

14. A metal film formed by coating a surface of a base material with the composite metal fine particle material of claim 1, and sintering the coated composite metal fine particle material.

15. A printed wiring board, on which the metal film of claim 14 is formed on a surface of a substrate as a wiring pattern.

16. A cable, wherein the metal film of claim 14 is formed on a periphery of an insulating layer covering a periphery of a conductive wire as a conductive layer.

17. A manufacturing method of a metal film, comprising the steps of:
coating a surface of a base material with a composite metal fine particle material, in which spherical silver nanoparticles are synthesized by using a silver compound, a solvent, a reducing agent, a dispersant, and conductive fillers composed of non-spherical metal fine particles, being dispersed in a solvent;
setting in a sintering furnace, the base material the surface of which is coated with the composite metal fine particle material; and
forming a metal film by sintering the composite metal fine particle material on the surface of the base material, with temperature/time conditions in the sintering furnace set to be 300° C. or less and 10 minutes or less.
